(19) United States
(12) Patent Application Publication
(10) Pub. No.: US 2005/0036285 A1
(43) Pub. Date: Feb. 17, 2005

(54) Portable computer

(75) Inventors: Cheon-Moo Lee, Suwon city (KR); Eun-Sik Jang, Suwon city (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-Si (KR)

(21) Appl. No.: 10/831,251

(22) Filed: Apr. 26, 2004

(30) Foreign Application Priority Data
Jul. 25, 2003 (KR) 2003-51628

(51) Int. Cl. H05K 5/00

(52) U.S. Cl. 361/683

(57) ABSTRACT

A portable computer system including a main body having a network controller controlling a network connection, a first Hard Disk Drive (HDD), and a first disk switching part for disconnecting the first HDD from the system. A docking unit is detachably attached to the main body, and a network switching part is installed in the docking unit. The network switching part allows the network controller to selectively access either an inner network or an outer network. A switching controller is installed in a side of either the main body or the docking unit, and controls the network switching part to access either the inner network or the outer network, and controls the first disk switching part to disconnect the first HDD from the system if the network controller accesses the outer network.

### CROSS-REFERENCE TO RELATED APPLICATION

This application claims the benefit of Korean Patent Application No. 2003-51628, filed Jul. 25, 2003 in the Korean Intellectual Property Office, the disclosure of which is incorporated herein by reference.

### BACKGROUND OF THE INVENTION

1. Field of the Invention

The present invention relates to a portable computer, and more particularly to a portable computer having improvements in security and portability.

2. Description of the Related Art

Computer and network technologies have shown remarkable development. Thus, vast quantities of information are provided through the Internet by connecting a network available computer to a network. Such computer networking is often divided into an inner network that is accessed through LAN (Local Area Network) and an outer network that is accessed through Internet, and a user can selectively access the inner network and the outer network as required to obtain required information.

Such computer networking technology developments provide convenience, but may cause personal information to be unwittingly released raising social issues. Additionally, hackers may actively seek to gain access to personal or proprietary information through the computer network. Therefore, developing security technology, such as a security solution for protecting business proprietary or sensitive information or personal information from leaking though the Internet (the outer network), is an important issue now.

One security approach is to separate the inner network and the outer network using a physical manner that includes having a network switching part and a disk switching part in a network card. The network card is installed in an expansion slot, such as a PCI (Peripheral Component Interconnect) slot. Hard Disk Drives (HDDs) for the inner network and outer network are installed in a computer and both HDDs are connected to a system by the disk switching part provided in the network card. Only a user that has passed an authentication process by entering an authentication key is permitted to access the inner network and the HDD for the inner network. That means, the disk switching part disconnects the access to the inner network, and also physically disconnects the HDD for the inner network from the system when the user does not complete the authentication process by not entering the authentication key, or failing to pass the authentication process.

Conventional security technology is only applied to a computer like a desktop computer, which has numerous expansion slots that can accommodate the network card having the network switching part and the disk switching part. However, it is difficult to apply to a portable computer that does not have spare expansion slots.

### SUMMARY OF THE INVENTION

It is an aspect of the present invention to provide a portable computer with a satisfactory level of security and portability.

Additional aspects and/or advantages of the invention will be set forth in part in the description which follows and, in part, will be obvious from the description, or may be learned by practice of the invention.

The foregoing and/or other aspects of the present invention are achieved by providing a portable computer comprising a main body having a network controller controlling a network connection, a first HDD (Hard Disk Drive), and a first disk switching part for disconnecting the first HDD from a system; a docking unit detachably provided in the main body; a network switching part installed in the docking unit to selectively access either an inner network or an outer network; and a switching installed at either the main body or the docking unit, and controlling the network switching part to allow the network controller to access either the inner network or the outer network, and controlling the first disk switching part to disconnect the first HDD from the system if the network controller accesses the outer network.

According to an aspect of the present invention, the portable computer further comprises a second HDD provided in the docking unit, and connected to the main body when the docking unit is installed in the main body.

According to an aspect of the present invention, the portable computer further comprises a second disk switching part controlled by the switching control part when the docking unit is installed in the main body, and connecting the second HDD to the main body if the network controller accesses the outer network, or disconnecting the second HDD from the main body if the network controller accesses the inner network.

According to an aspect of the present invention, the second HDD and the main body are connected to each other through a USB (Universal Serial Bus) interface.

According to an aspect of the present invention, the switching control part comprises a user authentication part enabling selection of the inner network depending on a user's operation, and that controls the network switching part to enable the network controller to access the inner network if the inner network is selected in the user authentication part.

According to an aspect of the present invention, the switching control part comprises a BIOS (Basic Input/Output System) program performing a POST (Power On Self Test), and the BIOS program controls the network switching part to enable the network controller to access either the inner network or the outer network based on an authentication signal recognized during the POST.

According to an aspect of the present invention, the BIOS program provides an authentication interface to receive the authentication signal during the POST

According to an aspect of the present invention, the BIOS program controls the network switching part to enable the network controller to access the inner network if the authentication signal inputted through the user authentication part and an authentication signal registered in advance are identical.

According to an aspect of the present invention, the BIOS program controls the first disk switching part to disconnect the first HDD from the system if the authentication signal inputted through the user authentication part and the authentication signal registered in advance are not identical.

According to an aspect of the present invention, the BIOS program controls the network switching part to enable the network controller to access the outer network if the authentication signal inputted through the user authentication part and the authentication signal registered in advance are not identical.

According to an aspect of the present invention, the first disk switching part cutoffs power supplied to the first HDD to disconnect the first HDD from the system.

According to another aspect of the present invention, the forgoing and/or other aspects may be also achieved by providing a portable computer comprising a network controller controlling a network; a BIOS (Basic Input/Output System) ROM (Read Only Memory) storing a BIOS program performing a POST (Power On Self Test); a first HDD (Hard Disk Drive); a network switching part controlling the network controller to selectively access either an inner network or an outer network; and a disk switching part disconnecting the first HDD from a system if the network controller accesses the outer network; and wherein the BIOS program controls the network switching part to enable the network controller to access either the inner network or the outer network based on an authentication signal recognized during the POST.

According to an aspect of the present invention, the BIOS program provides an authentication interface to receive the authentication signal during the POST

According to an aspect of the present invention, the BIOS program controls the network switching part to enable the network controller to access the inner network if the authentication signal inputted through the user authentication part and an authentication signal registered in advance are identical.

According to an aspect of the present invention, the BIOS program controls the disk switching part to disconnect the first HDD from the system if the authentication signal inputted through the user authentication part and the authentication signal registered in advance are not identical.

According to an aspect of the present invention, the BIOS program controls the network switching part to enable the network controller to access the outer network if the authentication signal inputted through the user authentication part and an authentication signal registered in advance are not identical.

According to an aspect of the present invention, the portable computer further comprises a second HDD, and wherein the disk switching part selectively connects one of the first HDD and the second HDD to the system according to the control of the BIOS program.

According to an aspect of the present invention, the portable computer further comprises a main HDD storing an OS (Operating System) program to boot up a system.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a perspective view of a portable computer according to an embodiment of the present invention;

FIG. 2 is a block diagram of the portable computer according to an embodiment of the present invention;

FIG. 3 is a block diagram of the portable computer according to an embodiment of the present invention;

FIG. 4 is a block diagram of the portable computer according to an embodiment of the present invention; and

FIG. 5 is a block diagram of the portable computer according to an embodiment of the present invention.

### DETAILED DESCRIPTION OF THE EMBODIMENTS

Reference will now be made in detail to the embodiments of the present invention, examples of which are illustrated in the accompanying drawings, wherein like reference numerals refer to like elements throughout. The embodiments are described below in order to explain the present invention by referring to the figures.

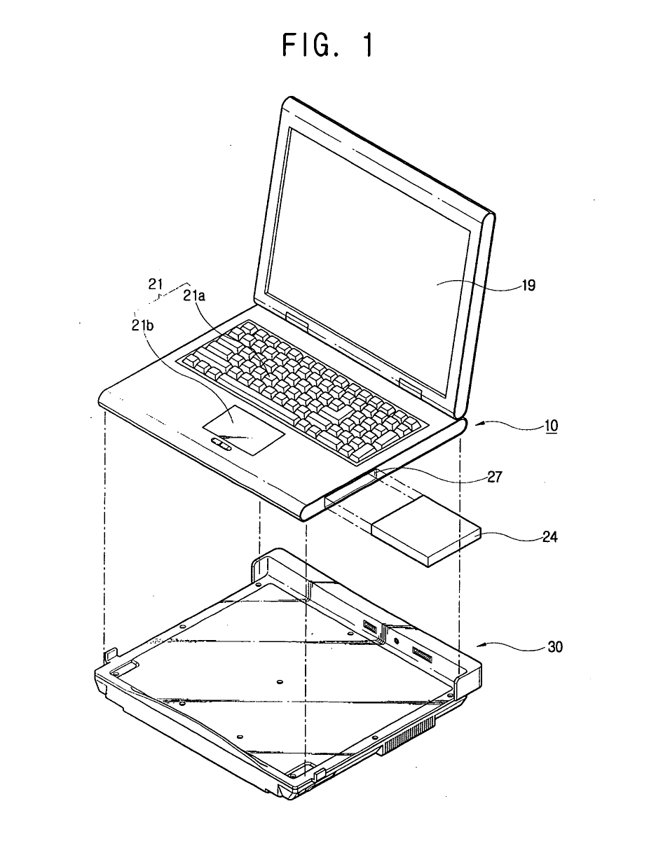

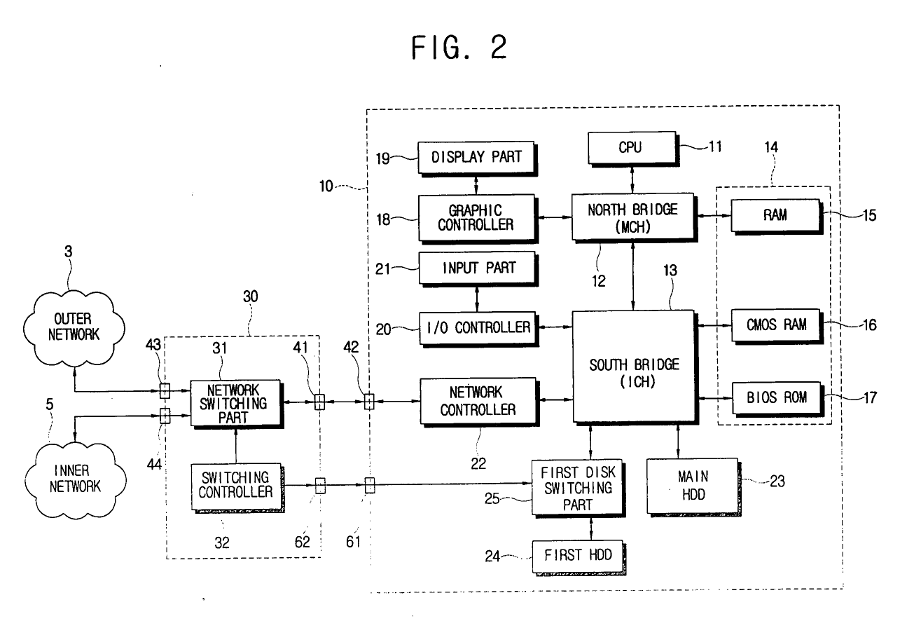

As shown in FIG. 1 and FIG. 2, a portable computer according to an embodiment of the present invention includes a main body 10, a network controller 22 controlling a network connection, a first Hard Disk Drive (HDD) 24 and a first disk switching part 25 to disconnect the first HDD 24 from a system. A docking unit 30 is detachably combined or attached to the main body 10. The portable computer also includes a network switching part 31 provided in the docking unit 30 to provide a path so that the network controller 22 can selectively access either an outer network 3 or an inner network 5. A switching controller 32 is provided in a side of either the main body 10 or the docking unit 30 and controls the network switching part 31 and the first disk switching part 25 to access the inner and outer networks 5 and 3 respectively.

The main body 10 includes a CPU (Central Processing Unit) 11, a memory part 14, a graphic controller 18 that is connected to a display part 19, an I/O (Input/Output) controller 20 to handle signals input from an input part 21 (such as a keyboard 21a, or a touch pad 21b), a north bridge 12 and a south bridge 13. However, it is understood that other types of input devices may be used, such as a touch screen or a mouse, and that the main body 10 can be otherwise configured to perform the same portable computer functions.

The memory part 14 includes a RAM (Random Access Memory) 15, a BIOS (Basic Inout/Ouput System) ROM (Read Only Memory) 17 storing a BIOS program performing a POST (Power-On Self-Test), and a CMOS (Complementary Metal Oxide Semiconductor) RAM 16. Alternatively, other types of memory can be used and the BIOS may be stored in other memory such as the maintenance cylinder of a hard disk or rewriteable memory.

The shown north bridge 12 is a chipset like a MCH (Memory Control Hub) that manages data flow between the CPU 12, the RAM 15, and the graphic controller 18. The south bridge 13 is also a chipset like an ICH (I/O Control Hub) that manages data flow between the I/O controller 20, the BIOS ROM 17, and the CMOS RAM 16.

The network controller 22 is connected to the south bridge 13, and processes data that is sent and/or received through the inner network 5 or the outer network 3, and is connected to a network connection port 42 externally exposed in the main body 10. Herein, a network connector (not shown), like a RJ-45 (Registered jack) connector connected to the inner network 5 and the outer network 3, is connected to the network connection port 42 and connects the main body 10 to the outer network 3 or the inner network 5.

The first HDD 24 is connected to the south bridge 13 through the first disk switching part 25. In this embodiment, the first HDD 24 is used for the inner network 5 only. The first HDD 24 is preferably set as a slave when connected to the system. That means, the portable computer includes a main HDD 23 set as a master, and the main HDD 23 stores an OS (Operation System) program performing system booting. Therefore, if the first HDD 24 is removed from the main body 10 for security when the main body 10 is connected to access the outer network 3, the main body 10 is still functional with the main HDD 23. However, it is understood that the master slave drive relationship is not required in all aspects of the invention, and that the main HDD 23 is not required to be used with the first HDD 24 in all aspects of the invention.

The first disk switching part 25 is controlled by the switching controller 32, and connects or disconnects the first HDD 24 to the system according to an authentication signal.

With the above configuration, the main body 10 can operate independently as a computer system according to the first embodiment of the present invention, and can access the outer network 3 and the inner network 5 according to the authentication signal. Herein, while not required in all aspects, the first HDD 24 is detachably combined to a bay 27 provided in a side of the main body 10, as shown in FIG. 1. Thus, the first HDD 24 can be easily detached from the main body 10 for added security when the system is accessing the outer network 3 using only the main body 10.

On the other hand, the docking unit 30 shown in FIG. 1 is detachably provided at a side of the main body 10. As shown in FIG. 1, the docking unit 30 is exemplarily formed as a docking station disposed in a bottom part of the main body 10, but it can be disposed in one of opposing sides of the main body 10, or inserted into a bay provided in a side of the main body 10. In an alternative aspect of the invention, the docking station could be a cradle to connect a portable digital assistant to a network.

When the docking unit 30 is engaged with the main body 10, the network switching part 31 is connected to the network controller 22 through connectors 41 and 42 respectively. The docking unit 30 also comprises an outer network connection port 43 to access the outer network 3 and an inner network connection port 44 to access the inner network 5. The outer network connection port 43 and the inner network connection port 44 are connected to the network switching part 31. The network switching part 31 operates to let the outer network 3 accessed through the outer network connection port 43, and the inner network 5 accessed through the inner network connection port 44, be selectively connected to the network controller 22 of the main body 10.

The switching controller 32 controls the network switching part 31 to allow the network controller 22 to access either the outer network 3 and/or the inner network 5. If the network controller 22 accesses the outer network 3, the switching controller 32 controls the first disk switching part 25 to disconnect the first HDD 24 from the system. In the main body 10 and the docking unit 30, connectors 61 and 62 respectively are disposed corresponding to each other and are connected to each other. Control signals generated from the switching controller 32 flow through the connector 62 of the docking unit 30 to the connector 61 of the main body 10 to the first disk switching part 25.

The switching controller 32 according to the first embodiment of the present invention may have a user authentication part (not shown) to selectively access the inner network 5 depending on a user's operation according to an aspect of the invention. Herein, the user authentication part is an authentication device to selectively access the inner network 5 and/or the first HDD 24 by entering a secure key. For example, the portable computer controls the network switching part 31 and the first disk switching part 25 to enable the network controller 22 to access the outer network 3, while the first HDD 24 is disconnected from the system. In this state, if the user selects the inner network 5 in the user authentication part using the secure key, the network switching part 31 and the first HDD 24 are controlled to make the network controller 22 access the inner network 5, and the first HDD 24 is connected to the system. Herein, operations of the network switching part 31 and/or the first disk switching part 25 are automatically controlled depending on the secure key entered by the user in the user authentication part, and are also controlled by applying a control signal for the secure key to the network switching part 31 and/or the first disk switching part 25. It is understood that the user authentication part may be implemented in the switching controller 32, and the network controller 22 and in a separate component depending on the preference of the designer. Additionally, the user authentication part may be implemented in either hardware or software.

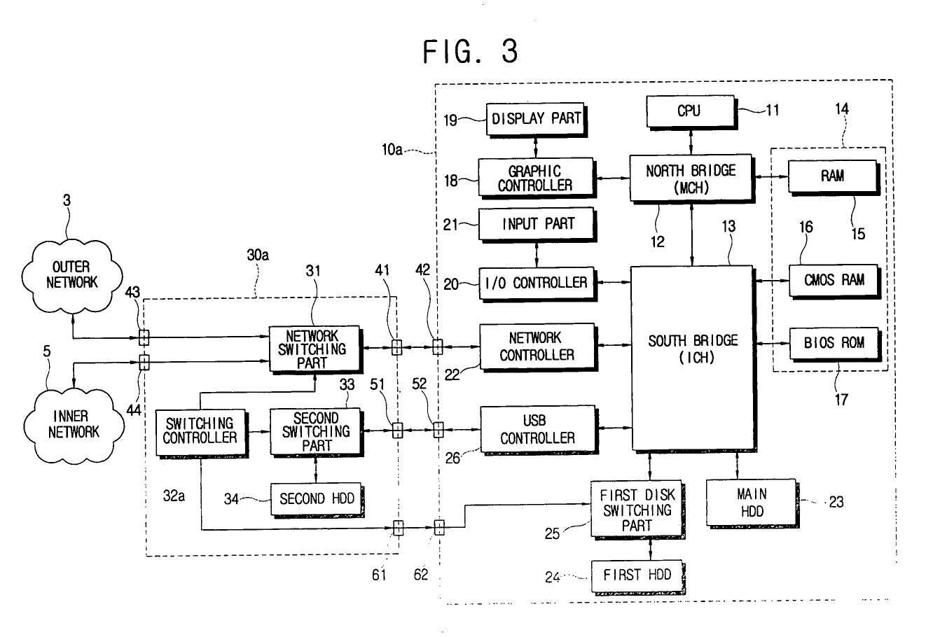

Hereinbelow, a portable computer according to an embodiment of the present invention will be described referring to FIG. 3. Herein, like components of the portable computer shown in FIGS. 1 and 2 will be marked with the same reference numbers used in FIG. 1 and related descriptions will be omitted.

The portable computer shown in FIG. 3 includes a second Hard Disk Drive (HDD) 34 installed in a docking unit 30a. The second HDD 34 is connected to a main body 10a if the docking unit 30a is installed in the main body 10a. In this embodiment, the second HDD 34 is used for the outer network 3 only. However, it is understood that the second HDD 34 could also be used with the inner network 3.

The second HDD 34 is connected to the main body 10a through a USB (Universal Serial Bus) interface. The USB interface includes an USB controller 26 and a USB connection port 52. The docking unit 30a has a USB connector 51 corresponding to the USB connection port 52. Thus, the second HDD 34 is connected to the system by the USB connector 51 connected to the USB connection port 52 if the docking unit 30a is attached to the main body 10a. The USB controller 26 may be built in the south bridge 13, thus the USB controller 26 and the south bridge 13 can be provided as a single chipset and as separate chipsets depending on the aspect of the present invention. Other peripheral interfaces such as serial, IEEE 1394 and USB 2.0 may also be used.

The portable computer shown in FIG. 3 has a second switching part 33 which connects and disconnects the second HDD 34 with respect to the main body 10a while the docking unit 30a is connected to the main body 10a. Herein, a switching controller 32a controls the second switching part 33 to make the second HDD 34 to be connected with the main body 10a when the network controller 22 accesses the outer network 3, and to be disconnected from the main body 10a when the network controller 22 accesses the inner network 5. Therefore, communication between the inner network 5 and the outer network 3 can be physically isolated by having the second HDD 34 connected to the system and the first HDD 24 disconnected from the system if the network controller is connected to the outer network 3, and the second HDD 34 disconnected from the system and the first HDD 24 connected to the system if the network controller is connected to the inner network 5.

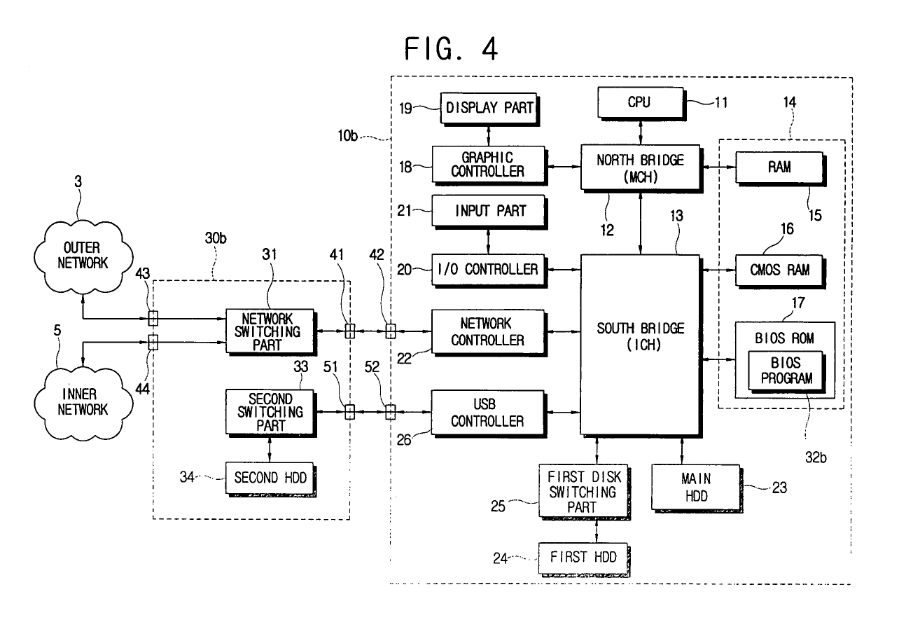

Hereinbelow, a portable computer according to another embodiment of the present invention will be described referring to FIG. 4. Herein, like components of the portable computer will be marked with the same reference numbers and related descriptions will be omitted.

A switching control part of the portable computer shown in FIG. 4 comprises a BIOS (Basic Input/Output System) program 32b performing a POST (Power On Self Test). The BIOS program 32b controls the network switching part 31 based on an authentication signal recognized during the POST performed by the BIOS program 32b. For example, the BIOS program 32b controls the network switching part 31 to make the network controller 22 connected with the inner network 5 if the authentication signal and a previously registered authentication signal are identical, and controls the network switching part 31 to make the network controller 22 connect to the outer network 3 if the authentication signal and the previously registered authentication signal are not identical. The BIOS program 32b also controls the first disk switching part 25 to enable the first HDD 24 to be connected to the system if the authentication signal recognized during the POST process and the registered authentication signal are identical, and controls the first switching part 25 to disconnect the first HDD 24 from the system if the authentication signal and the registered authentication signal are not identical.

Herein, the display part 19 may display an authentication interface to require a user to enter a password by the input part 21 to access the inner network 5, thus the BIOS program determines that the inputted authentication signal and the previously registered authentication signal are identical if the entered password and a registered password are identical. However, other input techniques and displays can be used for authentication, such as mechanical or electronic keys, control pads, or electronic passwords to identify and authenticate a user.

In this embodiment, the user authentication part is operated by entering the secure key according to the first embodiment of the present invention, using an input/output pin of a GPIO (General Purpose Input/Output) (not shown) connected to the user authentication part. Herein, the BIOS program 32b checks whether or not the input/output pin of the GPIO is activated during the POST. The BIOS program 32b determines the inputted authentication signal and the registered authentication signal to be identical if the input/output pin of GPIO is activated.

On the other hand, the BIOS program 32b can control the second disk switching part 33 installed in the docking unit 30b depending on the authentication signal recognized during the POST Thus, communication between the inner network 5 and the outer network 3 can be physically isolated separated by having either the first HDD 24 or the second HDD 34 connected to the system depending on an authentication signal when the portable computer is booting up.

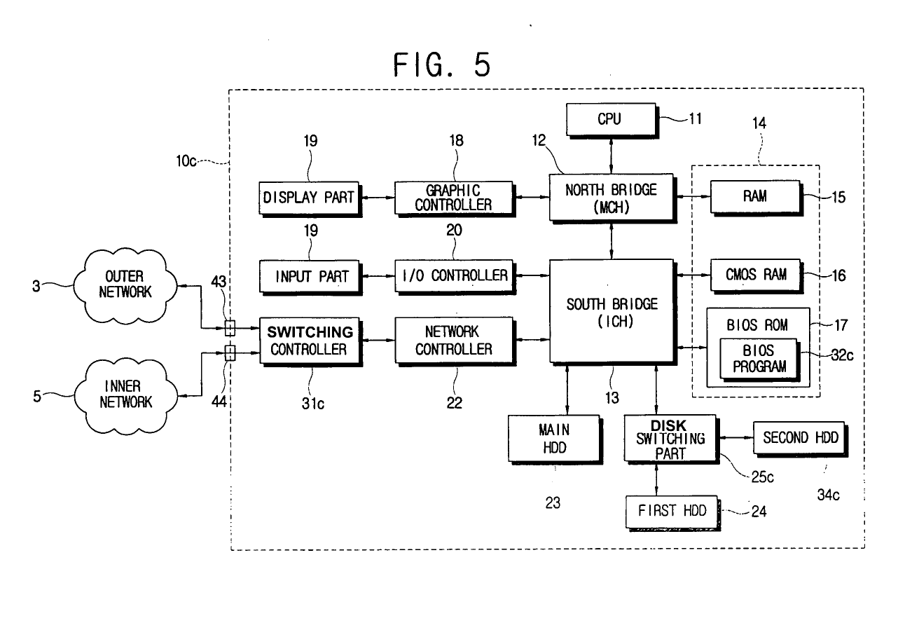

Hereinbelow, a portable computer according to another embodiment of the present invention will be described referring to FIG. 5. In the portable computer shown, a network switching part 31c is installed in a main body 10c. A switching control part also comprises a BIOS program 32c as described in embodiment shown in FIG. 4. Herein, the BIOS program 32c controls the network switching part 31c to enable the network controller 22 to access individually the inner network 5 and the outer network 3 based on an authentication signal recognized during a POST The BIOS program 32c also controls a disk switching part 25c to disconnect the first HDD 24 from the system if the network controller 22 accesses the outer network 3.

A second HDD 34c is installed in the main body 10c as shown in FIG. 5. Herein, the disk switching part 25c is provided to enable either the first HDD 24 or the second HDD 34c to be selectively connected to the system. That is, the BIOS program 32c controls the disk switching part 25c to allow either the first HDD 24 and/or the second HDD 34 to be selectively connected to the system based on the authentication signal recognized during the POST. However, the second HDD 34 is not required to be used in all aspects of the invention.

The process of the BIOS program 32c recognizing the authentication signal during the POST is the same as in the embodiment of the present invention shown in FIG. 4, and therefore will be omitted.

In the above embodiments, the second HDDs 34 and 34c are exemplified as separately installed and used for the outer network 3 only. However, it is understood that the main HDD 23 also can be used as a HDD for the outer network 3 because it requires less security. If the main HDD 23 is used for the outer network 3 the main HDD 23 should stay connected to the system regardless of whether the portable computer accesses the inner network 5 or the outer network 3.

Also, the first disk switching part 25 and the disk switching part 25c in the above embodiments cutoff power supplied to the first HDD 24 to disconnect the first HDD 24 from the system, and thereby disconnect a data line connecting the first disk switching part 25, the disk switching part 25c, and the system respectively.

As described above, the portable computer provides satisfactory security and portability by having the main body in which the network controller controlling the network connection, the first HDD, and the first disk switching part to disconnect the first HDD from the system are installed. The docking unit is detachably attached to the main body 10, and the network switching part installed in the docking unit is controlled by the network controller to access either the inner network or the outer network. The switching controller may be installed in a side of either the main body or the docking unit, and controls the network switching part to access either the inner network or the outer network, and the first disk switching part to disconnect the first HDD from the system if the network controller accesses the outer network.

To improve security, security-related components such as the network switching part, the switching controller, and the like are provided in the docking unit detachably attached to the main body. The main body 10 also functions as a working computer system. Accordingly users may purchase the docking unit if necessary, thereby increasing marketability of the portable computer.

With the above configuration, the present invention provides a portable computer with a satisfactory level of security and portability. While described with reference to hard disk drives, it is understood that other types of storage media such as optical discs like CD-ROM, CD-R, CD-RW, or DVD-R and flash memory may be used.

Although a few embodiments of the present invention have been shown and described, it will be appreciated by those skilled in the art that changes may be made in these embodiments without departing from the principles and spirit of the invention, the scope of which is defined in the appended claims and their equivalents.

1. A portable computer comprising:
a main body having a network controller controlling a network connection, a first Hard Disk Drive (HDD), and a first disk switching part for disconnecting the first HDD from a system;
a docking unit detachably attached to the main body;
a network switching part installed in the docking unit to selectively access an inner network and an outer network; and
a switching control part installed at either the main body or the docking unit and which controls the network switching part to allow a network controller to individually access the inner network and the outer network, and controls the first disk switching part to disconnect the first HDD from the portable computer if the network controller accesses the outer network.

2. The portable computer according to claim 1, further comprising a second HDD provided in the docking unit which is connected to the main body when the docking unit is installed at the main body.

3. The portable computer according to claim 2, further comprising a second disk switching part controlled by the switching control part when the docking unit is installed at the main body, and which connects the second HDD to the main body if the network controller accesses the outer network, and disconnects the second HDD from the main body if the network controller accesses the inner network.

4. The portable computer according to claim 2, wherein the second HDD and the main body are connected to each other through a USB (Universal Serial Bus) interface.

5. The portable computer according to claim 3, wherein the switching control part further comprises a user authentication part to control the network switching part to enable the network controller to access the inner network if the inner network is selected in the user authentication part.

6. The portable computer according to claim 3, wherein the switching control part comprises a BIOS (Basic Input/Output System) program performing a POST (Power On Self Test), and the BIOS program controls the network switching part to enable the network controller to individually access either the inner network and the outer network based on an authentication signal recognized during the POST.

7. The portable computer according to claim 6, wherein the BIOS program provides an authentication interface to receive the authentication signal during the POST.

8. The portable computer according to claim 7, wherein the BIOS program controls the network switching part to enable the network controller to access the inner network if the authentication signal input through the authentication interface and an authentication signal registered in advance are identical.

9. The portable computer according to claim 8, wherein the BIOS program controls the first disk switching part to disconnect the first HDD from the system if the authentication signal input through the authentication interface and the authentication signal registered in advance are not identical.

10. The portable computer according to claim 9, wherein the BIOS program controls the network switching part to enable the network controller to access the outer network if the authentication signal input through the authentication interface and the authentication signal registered in advance are not identical.

11. The portable computer according to claim 1, wherein the first disk switching part controls power supplied to the first HDD to disconnect the first HDD from the system.

12. A portable computer comprising:
a network controller controlling a network connection;
a BIOS (Basic Input/Output System) ROM (Read Only Memory) storing a BIOS program performing a POST (Power On Self Test);
a first HDD (Hard Disk Drive);
a network switching part to allow a network controller to selectively access either an inner network and an outer network; and
a disk switching part disconnecting the first HDD from the portable computer if the network controller accesses the outer network;
wherein the BIOS program controls the network switching part to enable the network controller to independently access the inner network and the outer network based on an authentication signal recognized during the POST.

13. The portable computer according to claim 12, wherein the BIOS program provides an authentication interface to receive the authentication signal during the POST.

14. The portable computer according to claim 13, wherein the BIOS program controls the network switching part to enable the network controller to access the inner network if the authentication signal input through the authentication interface and an authentication signal registered in advance are identical.

15. The portable computer according to claim 13, wherein the BIOS program controls the disk switching part to disconnect the first HDD from the the portable computer if the authentication signal input through the authentication interface and an authentication signal registered in advance are not identical.

16. The portable computer according to claim 15, wherein the BIOS program controls the network switching part to enable the network controller to access the outer network if the authentication signal input through the authentication interface and an authentication signal registered in advance are not identical.

17. The portable computer according to claim 12, further comprising a second HDD, wherein the disk switching part selectively connects the first HDD and the second HDD to the system.

18. The portable computer according to claim 12, further comprising a main HDD storing an OS (Operating System) program to boot up the system.

19. The portable computer according to claim 17, further comprising a main HDD storing an OS (Operating System) program to boot up a system.

20. A security enhancement method in a system including a docking station and a portable computer with a memory capable of being coupled to the docking station, comprising:
establishing a connection to one of a first network and a second network from the docking station when coupled to the portable computer;
establishing a connection to the memory when the connection to the second network is established.

21. The method of claim 20, further comprising severing automatically the connection to the memory when the connection to the first network is established.

22. The method of claim 20, further comprising establishing an authentication interface to verify a user, wherein:
the establishing the connection to one of a first network and a second network comprises establishing a connection to the second network when the user is verified using data received from the established authentication interface, and
the establishing the connection to the memory comprises establishing a connection to the memory when the user is verified.

23. The method of claim 22, further comprising severing automatically the connection to the memory and the second network when the user is not verified using data received from the established authentication interface.

24. A computer readable storage medium encoded with processing instructions for implementing a method of establishing the connection to the first and second networks and the memory as recited by claim 23 performed by a processor.

25. A system comprising:
a docking station and a portable computer with at least one memory capable of being coupled to the docking station;
a plurality of connectors to couple the portable computer and the docking station;
a network switching selector disposed in the docking station to selectively access an inner network and an outer network;
a memory switching selector disposed in the computer to selectively access the memory; and
a controller to control the network switching selector and the memory switching selector, wherein the memory is accessed only when the inner network is accessed.

26. The system of claim 25, further comprising:
an authentication input device that sends signals to the controller, wherein a user is authenticated if a predetermined code is input, and a connection to the inner network and to the secure hard disk drive is established when the user is verified.

27. The system of claim 25, wherein the controller is disposed in the docking station.

28. The system of claim 26, wherein the controller is disposed in the portable computer.

29. The system of claim 25, wherein the memory switching selector removes power to the memory when the controller is setting the network switching selector to access the outer network.

30. The system of claim 25, further comprising a user authentication Basic Input/Output System program on a memory storage unit that controls a processor to send a password entry message to a display of the portable computer when the portable computer is turned on, wherein a user is authenticated if a predetermined code is entered using an input of the portable computer, and a connection to the inner network and to the memory is established when the user is authenticated if the user is authenticated.

31. A system including a portable computer and first and second memories, comprising:
means within the portable computer for authenticating a user to produce an authentication result;
a network switching selector to selectively access an inner network and an outer network;
a memory switching selector to selectively access the first memory and the second memory; and
a controller to control the memory switching selector, wherein the first memory and the second memory are accessed based on the authentication result of the means for authenticating the user.

32. The system of claim 31, wherein the controller controls the network switching selector to access the inner network based on the authentication result of the means for authenticating the user.

33. A system including a docking station and a portable computer with at least one memory capable of being coupled to the docking station comprising:
means for interactively coupling said portable computer to said docking station;
means for establishing a user authentication interface within the portable computer to selectively enable access by a user to an inner network and a memory of said portable computer if a predetermined code is entered correctly;
means for selectively accessing an inner network and an outer network;
means for selectively accessing the memory; and
means within the portable computer for automatically disabling the memory and the access to the inner network when the user enters the predetermined code incorrectly;
means for enabling access to the memory only when the inner network is accessed and the user entered the predetermined code correctly; and
means for automatically disabling the memory when the outer network is accessed, regardless of whether the user entered the predetermined code correctly.
